(19) United States
(12) Patent Application Publication
(10) Pub. No.: US 2025/0294933 A1
(43) Pub. Date: Sep. 18, 2025

(54) LED PACKAGING STRUCTURE

(71) Applicant: Violumas, Inc., Fremont, CA (US)

(72) Inventors: Pao H. CHEN, Milpitas, CA (US); Yeh Chia TSENG, Fremont, CA (US)

(21) Appl. No.: 18/607,013

(22) Filed: Mar. 15, 2024

(51) Int. Cl. H01L 33/60

(52) U.S. Cl. CPC H10H 20/856

(57) ABSTRACT

A LED device package structure includes an LED device mounted on a substrate; a wing-lens placed over the LED device, and the wing-lens includes a lens and an extension structure forming an all-around platform near a bottom edge of the lens; and a recess area formed between the bottom surface of the extension structure and the top surface of the substrate outside a sidewall of the lens at the bottom edge of the lens; a coating layer disposed on the bottom surface of the extension structure and the sidewall of the lens at the bottom edge of the lens; and an adhesive material applied in the recess area around the platform to seal the wing-lens to the substrate. The wing-lens can be a wing-Fresnel lens or a wing-cap in an optical window housing. The coating layer blocks side-emitted UV lights from interacting with the UV sensitive adhesives.

### FIELD OF THE INVENTION

This application is related to optical system packaging technology, in particular, it is about LED light packaging structures and methods for making the same.

### BACKGROUND

In the past few years, light emitting diode (LED) devices emitting in the visible spectra have successfully replaced incandescent light bulbs and most fluorescent tubes, so have become the dominant light sources for general illumination purposes. At the same time, wavelength-specific ultraviolet (UV) LED devices have followed this trend and have gradually replaced the traditional UV light sources, such as xenon, mercury or tungsten halogen lights.

However, unlike in most general lighting situations where an omnidirectional emission is preferred, most UV light applications require directionally emitted light beams to ensure that the photonic energy is focused within a desired radiant angle. Therefore, optical subsystems such as various lenses and other optical parts for directional emission have become the typical components to be associated with UV LED devices.

FIG. 1A and FIG. 1B show two types of traditional LED packages respectively, where a LED die, 1002 or 1012, is bonded on its associated circuit substrate 1001 or 1011. A spherical optical lens 1003 in FIG. 1A or an optical cap 1013 in FIG. 1B, is assembled on the surface of the circuit substrate 1001 or 1011, to enclose the LED die 1002 or 1012 inside the optical lens 1003 or optical cap 1013 respectively. To hermetically seal the optical lens 1003 or optical cap 1013 to the circuit substrate, typically an adhesive is used as the part 1004 shown in FIG. 1A and 1014 in FIG. 1B. Optical rays 1005 in FIG. 1A or 1015 in FIG. 1B are examples showing the emission of photons from the LED die 1002 through the optical lens 1003 or from the die 1012 through the optical cap 1013, respectively. However, these traditionally assembled LED packages always suffer from poor reliability, mostly because the optical lenses or the optical caps are likely to detach from its surface of the circuit substrate after extensive usage.

FIG. 2A and FIG. 2B illustrate, in addition to the forward emitting lights 1005 or 1015, stray lights 2006 or 2016 emitted from the sides of the LED die 1002 or 1012 respectively, shown as dashed arrow lines. Side-emission of LED dies is often neglected in most applications, because it only presents less than 10% of the LED's total power, and it does not propagate in the desired direction. However, it is often the main cause contributing to the poor reliability of the current UV LED packages. As shown in FIG. 2A and FIG. 2B, side-emitted light rays 2006 or 2016 interact with the adhesive 1004 or 1014 that seals the optical lens 1003 or the optical cap 1013 onto its circuit substrates 1001 or 1011. Unfortunately, most adhesive materials possess the characteristic of degradation under any UV exposure, so such weakness results in eventual detachment of the optical lens and optical cap away from their circuit substrates, leading to a shorter life of the UV LED device packages. There is an urgent issue that needs to be resolved.

### SUMMARY

The embodiments of the invention described herein provide an LED device package structure, including an LED device mounted on a top surface of a substrate; a wing-lens placed over the LED device and on the top surface of the substrate, wherein the wing-lens comprises: a lens and an extension structure forming a platform around the lens and near a bottom edge of the lens, and a recess area is formed between a bottom surface of the extension structure and the top surface of the substrate outside a sidewall of the lens at the bottom edge of the lens; a coating layer disposed on the bottom surface of the extension structure as well as the sidewall of the lens at the bottom edge of the lens; and an adhesive material applied in the recess area around the platform to seal the wing-lens to the substrate.

In some examples, the lens is a convex or spherical lens

In some examples, the lens is a Fresnel lens.

In some examples, the extension structure around the lens comprises one of a ring shape, a square shape, and a polygon shape.

In some examples, the LED device emits ultraviolet (UV) light.

In some examples, the wing-lens comprises one of fused silica (quartz) or other UV transparent materials.

In some examples, a material in the coating layer comprises a metal or a combination of metals, for example, aluminum (AL), copper (CO), or gold (AU), which are reflective to UV light, and wherein the coating layer is deposited via one of techniques, including but not limited to, physical vapor deposition (PVD), chemical vapor deposition (CVD), electroplating, or plasma-enhanced chemical vapor deposition (PECVD), etc.

In some examples, a material in the coating layer comprises a metal or a combination of metals, for example, tungsten (TW), platinum (Pt), nickel (Ni), iron (Fe) or chromium (Cr), which are absorptive to UV light, and the coating layer is deposited via one of techniques, including but not limited to, physical vapor deposition (PVD), chemical vapor deposition (CVD), electroplating, or plasma-enhanced chemical vapor deposition (PECVD), etc.

In some examples, a material in the coating layer comprises inorganic materials, such as silicon oxide that absorbs or blocks UV photons.

The embodiments of the invention described herein also provide another LED device package structure, including: an LED device mounted on a top surface of a substrate; a wing-cap placed over the LED device and on the top surface of the substrate, wherein the wing-cap comprises: an optical window housing and an extension structure forming a platform around the optical window housing and near a bottom edge of the optical window housing, and a recess area is formed between a bottom surface of the extension structure and the top surface of the substrate outside a sidewall of the optical window housing at the bottom edge of the optical window housing; a coating layer disposed on the bottom surface of the extension structure, as well as the sidewall of the optical window housing at the bottom edge of the optical window housing; and an adhesive material applied in the recess area around the platform to seal the optical window housing to the substrate.

In some examples, the optical window housing includes a flat transparent window.

In some examples, the extension structure around the optical window housing comprises one of a ring shape, a square shape, and a polygon shape.

### BRIEF DESCRIPTION OF THE DRAWINGS

Having thus described the invention in general terms, reference will now be made to the accompanying drawings, which are not necessarily drawn to scale, and wherein:

FIG. 1A shows a schematic of a type of a traditional LED package and FIG. 1B shows a schematic of another type of a traditional LED package, both have LED dies bonded on the circuit substrates;

FIG. 2A and FIG. 2B show stray lights emitted from the sides of the LED dies in traditional LED packages;

FIG. 3A shows a schematic cross section of a ring-shaped wing-lens structure for a LED package,

FIG. 3B shows a schematic perspective from above a ring-shaped wing-lens structure for a LED package, and FIG. 3C shows a schematic perspective from below a square-shaped wing-lens structure for a LED package, according to the embodiments of the application;

FIG. 4 illustrates a schematic of a cross sectional view of the assembled LED package structure with a wing-lens according to the embodiments of the application;

FIG. 5 illustrates a schematic of a wing-cap structure for an LED package according to the embodiments of the application;

FIG. 6 illustrates a schematic of a cross sectional view of the assembled LED package structure with a wing-cap according to the embodiments of the application;

FIG. 7A shows a schematic of a wing-Fresnel lens structure for an LED package, FIG. 7B shows a schematic cross-section of a wing-Fresnel lens and its associated extension for the LED package, and FIG. 7C shows the 3D-like perspective view of the wing-Fresnel lens and the wing extension; and

FIG. 8 illustrates a schematic of a cross sectional view of an assembled LED package structure with a wing-Fresnel lens, according to the embodiments of the application.

### DETAILED DESCRIPTION OF THE DISCLOSURE

The present invention now will be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout. As used herein, terms such as “top,” “bottom,” “front,” etc. are used for explanatory purposes in the examples provided below to describe the relative position of certain components or portions of components. Accordingly, as an example, the term “top current spreading layer” may be used to describe a current spreading layer; however, the current spreading layer may be on the top or on the bottom, depending on the orientation of the particular item being described.

It should be understood that the examples and embodiments described herein are for illustrative purposes only and that various modifications or changes in light thereof will be suggested to persons skilled in the art and are to be included within the spirit and purview of this application.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

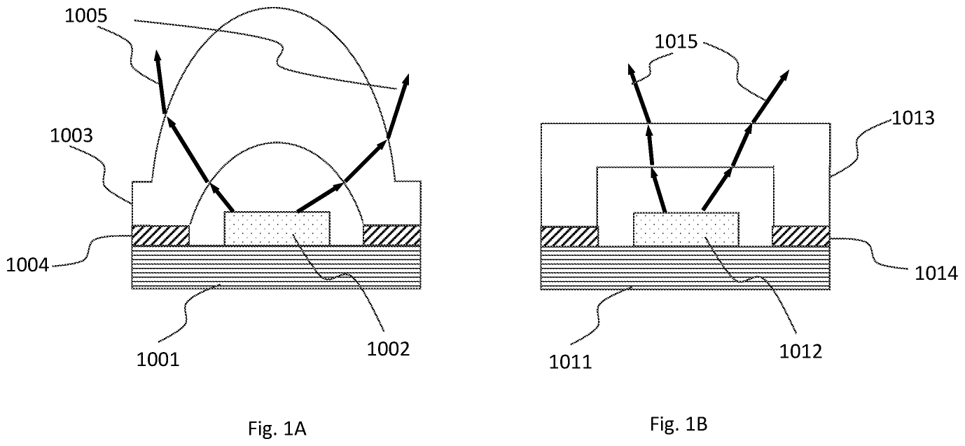

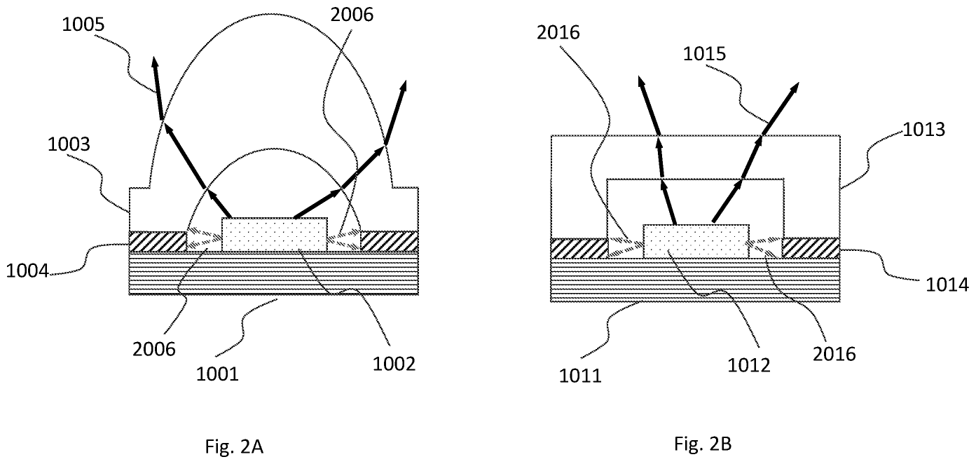

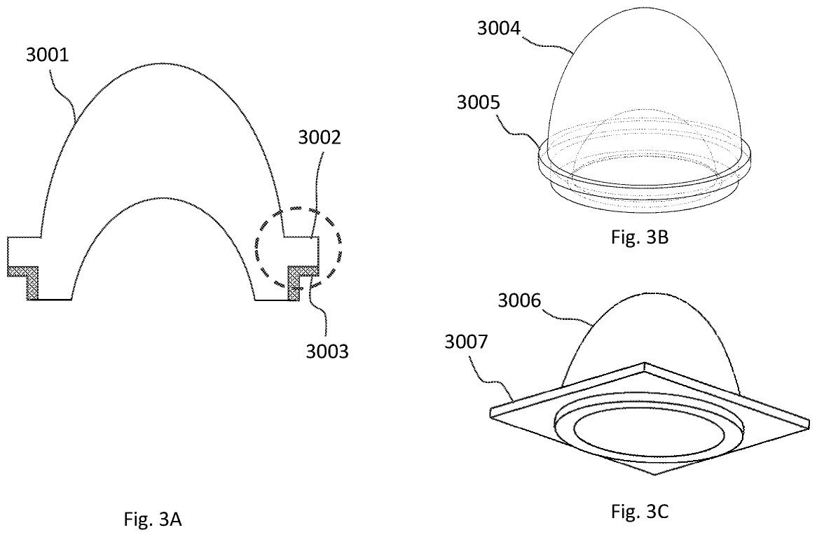

One embodiment of the application discloses a novel optical wing-lens structure. FIG. 3A shows a wing-lens 3001 to replace the conventional optical lens 1003 in FIG. 1A. A wing-lens 3001 includes a platform-shaped extension 3002 stretching out from near the bottom edge of the lens, like a wing which surrounds the entire lens structure. The wing-lens can be a convex or spherical lens. The wing-lens is made of fused silica (quartz) or other UV transparent materials.

A layer of coating 3003 is deposited both on the bottom surface of the wing-like extension and the side surface of the lens under the wing-like extension, as shown in the dashed circle. This coating can be either reflective or absorptive to the stray light from the UV LED die.

The coating material comprises one or a combination of metal and alloy materials, for example, aluminum (Al), copper (Cu), and gold (Au), which reflects UV photons. The layer of coating 3003 is deposited onto the targeted surface via one of the techniques, including but not limited to, physical vapor deposition (PVD), chemical vapor deposition (CVD), electroplating, or plasma-enhanced chemical vapor deposition (PECVD), etc.

Other metals such as tungsten (W), platinum (Pt), nickel (Ni), iron (Fe) and chromium (Cr) can be deposited via similar processes as mention above to absorb UV photons. The materials being reflective or absorptive will block the penetration of UV photons from invading the adhesives.

Inorganic materials, such as most glasses made of silicon oxide that can absorb or block UV photons are also suitable candidates for the coating materials 3003. These coating materials, either metals, alloys, or inorganic materials will not degrade under the side-emitting light exposure from the UV LED. The wing-lens extension may have different shapes. For example, FIG. 3B shows a ring-like round extension 3005 surrounding the wing-lens structure 3004, and FIG. 3C shows a square-shaped extension 3007 surrounding the wing-lens structure 3006.

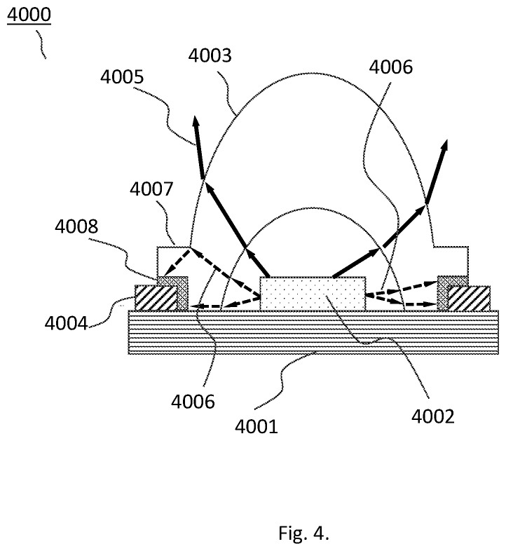

FIG. 4 illustrates a cross sectional view of the assembled LED package structure 4000 according to the embodiments of the application in FIG. 3A and FIG. 3B. In FIG. 4, a wing-lens 4003 is mounted on the top surface of a LED circuit substrate 4001 where an LED die 4002 is seated on. The wing-lens 4003 includes an extruded edge extension 4007 at a location close to the bottom lens edge, a coating layer 4008 disposed at both the bottom surface of the extension and the sidewall surface of the wing-lens under the extension structure. The wing-lens 4003 is seated on top of the circuit substrate 4001, forming a recess area between the extension 4007 of the wing-lens 4003 and the top surface of the circuit substrate 4001 with the recess area surrounding the wing-lens 4003. An adhesive layer 4004 is disposed all-around into the recess area under the lens extension 4007. The adhesive layer 4004 in the recess area seals the top surface of the substrate 4001 and the coating layer 4008 under the extension structure 4007.

The height of the extension platform bottom above the substrate is arranged to be in a range of 1 micron to 1 millimeter, but can be adjusted according to real situations.

In the disclosed LED package structure 4000 in FIG. 4, the side-emitted light rays 4006, shown as dashed arrow lines, are eliminated by either reflection or absorption by the coating layer 4008, so only the upward light rays 4005 leave the wing-lens 4003. The adhesive material 4004 hidden behind the coating layer 4008 is thus protected from the UV photons by the coating layer 4008. As a result, the material degradation of the adhesive material 4004 is therefore minimized.

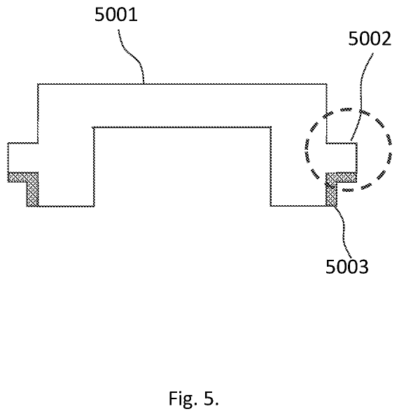

FIG. 5 illustrates another novel type of the optical design—a wing-cap to replace the conventional optical lens 1013 in FIG. 1B. The wing-cap window housing 5001 includes an extruding platform extension 5002 stretching out near the bottom edge of the wing-cap, like a wing which surrounds the entire window structure. The wing-cap window housing is made of fused silica (quartz) or other UV transparent materials.

A layer of coating 5003 is deposited both on the bottom surface of the wing-like extension and the side surface of the lens under the wing-like extension, as shown in the dashed circle. This coating can be either reflective or absorptive to the stray light emitted from the UV LED die.

The coating material comprises one or a combination of metal and alloy materials, for example, aluminum (Al), copper (Cu), and gold (Au), which reflects UV photons. The layer of coating 5003 is deposited onto the targeted surface via one of the techniques, including but not limited to, physical vapor deposition (PVD), chemical vapor deposition (CVD), electroplating, or plasma-enhanced chemical vapor deposition (PECVD), etc.

Other metals such as tungsten (W), platinum (Pt), nickel (Ni), iron (Fe) and chromium (Cr) can be deposited via similar processes as mention above to absorb UV photons. The materials being reflective or absorptive will block the penetration of UV photons from invading the adhesives.

Inorganic materials, such as most glasses made of silicon oxide that can absorb or block UV photons are also suitable candidates for the coating materials 5003. These coating materials, either metals, alloys, or inorganic materials will not degrade under the side-emitting light exposure from the UV LED. The wing-lens extension may have different shapes, including but not limited to square, rectangular, or polygon shapes.

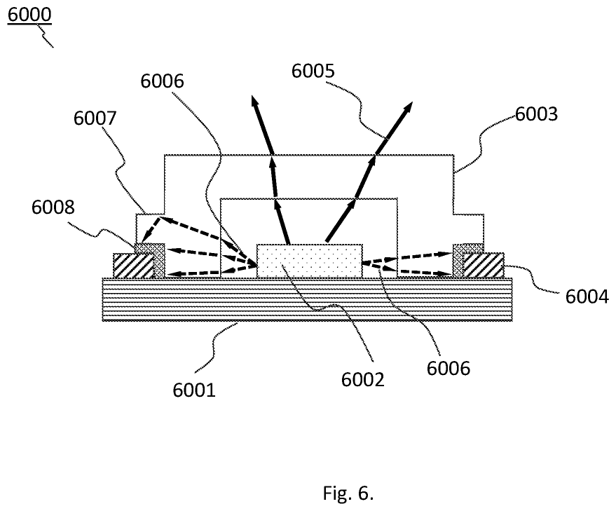

FIG. 6 illustrates a cross sectional view of the win-cap type assembled LED package structure 6000 according to the embodiment of the application in FIG. 3C and FIG. 5. In FIG. 6, a wing-cap optical window housing 6003 is mounted on the top surface of a LED circuit substrate 6001 where an LED die 6002 is seated on. The wing-cap window housing 6003 includes an extruded edge extension 6007 close to the win-cap bottom edge, a layer of coating 6008 disposed at both the bottom surface of the extension and the sidewall surface of wing-cap window housing under the extension 6007. The wing-cap window housing 6003 is seated on top of the circuit substrate 6001, forming a recess area between the extension 6007 of the wing-cap window housing 6003 and the top surface of the circuit substrate 6001 surrounding the wing-cap window housing 6003. An adhesive layer 6004 is disposed into the recess area under the cap extension 6007. The adhesive layer 6004 seals the top surface of the substrate 6001 to the coating layer 6008 under the extension structure 6007 in the recess.

The optical window housing includes a flat transparent window.

In the disclosed LED package structure 6000, the side-emitted light rays 6006, shown as dashed arrow lines, are eliminated by either reflection or absorption by the coating layer 6008, so only the upward light rays 6005 leave the wing-cap window housing 6003. The adhesive material 6004 hidden behind the coating layer 6008 is thus protected from the UV photons by the coating layer 6008. As a result, the material degradation of the adhesive material 6004 is therefore minimized.

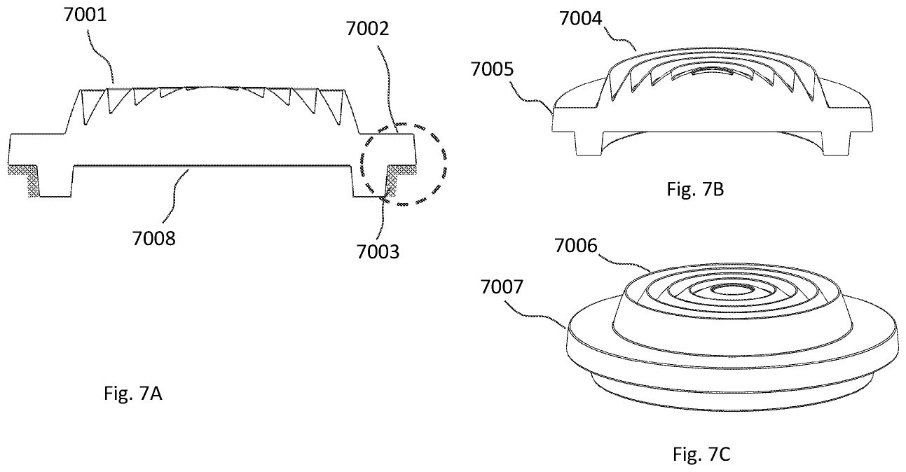

Another embodiment of the application discloses another novel optical wing-Fresnel lens structure to replace the conventional Fresnel-lens in the LED package. FIG. 7A shows a wing-Fresnel lens 7001 structure, which adds extruding platform-shape extension 7002 over a conventional Fresnel lens. Similar to a conventional Fresnel lens, there is a wide bottom recess 7008 as part of the optical lens design. The wing-Fresnel lens 7001 includes a platform-shaped extension 7002 stretching out from a location slightly above the bottom edge of the entire lens, like a wing which surrounds the lens structure. The wing-Fresnel lens is made of fused silica (quartz) or other UV transparent materials.

A layer of coating 7003 is deposited both on the bottom surface of the wing-like extension and the side surface of the lens under the wing-like extension, as shown in the dashed circle. This coating can be either reflective or absorptive to the stray light from the UV LED die.

The height of the extension platform bottom above the substrate is in a range of 1 micron to 1 millimeter, but can be adjusted according to real applications.

The coating material comprises one or a combination of metal and alloy materials, for example, aluminum (Al), copper (Cu), and gold (Au), which reflects UV photons. The layer of coating 7003 is deposited onto the targeted surface via one of the techniques, including but not limited to, physical vapor deposition (PVD), chemical vapor deposition (CVD), electroplating, or plasma-enhanced chemical vapor deposition (PECVD), etc.

Other metals such as tungsten (W), platinum (Pt), nickel (Ni), iron (Fe) and chromium (Cr) can be deposited via similar processes as mention above to absorb UV photons. The materials being reflective or absorptive will block the penetration of UV photons from invading the adhesives.

Inorganic materials, such as most glasses made of silicon oxide that can absorb or block UV photons are also suitable candidates for the coating materials 7003.

These coating materials, either metals, alloys, or inorganic materials will not degrade under the side-emitting light exposure from the UV LED.

FIG. 7B shows a cross-section of a wing-Fresnel lens 7004 including its associated extension. FIG. 7C shows the 3D-like perspective view of the wing extension 7007 and the wing-Fresnel lens 7006.

The wing-Fresnel lens extension may have different shapes. For example, FIG. 3B/FIG. 3C show a ring-like round extension 7005/7007 surrounding the wing-Fresnel lens structure 7004/7006. But the lens extension can be square, rectangular or polygon shaped.

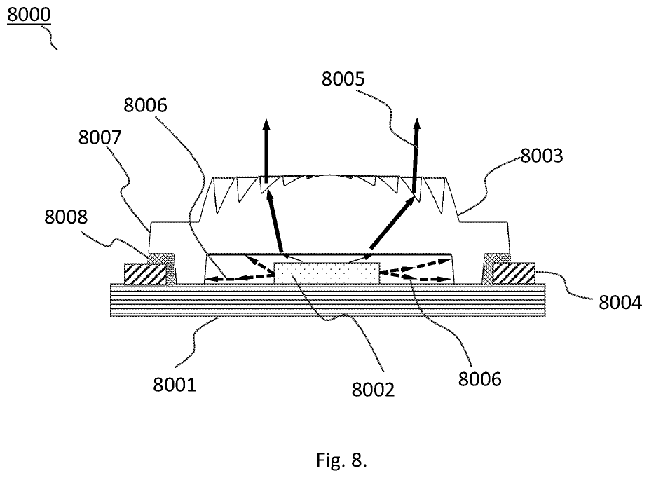

FIG. 8 illustrates a cross sectional view of a wing-Fresnel lens assembled LED package structure 8000 according to the embodiment of the application in FIGS. 7A-7C. In FIG. 8, a wing-Fresnel lens 8003 is mounted on the top surface of a LED circuit substrate 8001 where an LED die 8002 is seated. The wing-Fresnel lens 8003 includes an extruded edge extension 8007 slightly above the lens bottom edge, a layer of coating 8008 disposed at both the bottom surface of the extension and the sidewall surface of the wing-Fresnel lens under the extension. The wing-Fresnel lens 8003 is seated on top of the circuit substrate 8001, forming a recess area between the extension 8007 of the wing-Fresnel lens 8003 and the top surface of the circuit substrate 8001, and the recess area surrounds the wing-Fresnel lens 8003. An adhesive layer 8004 is disposed into the recess area under the lens extension 8007. The adhesive layer 8004 seals from the coating layer 8008 under the extension 8007 to the top surface of 8001.

In the disclosed wing-Fresnel lens LED package structure 8000, the side-emitted light 8006, shown as dashed arrow lines, is eliminated by either reflection or absorption by the coating layer 8008. The adhesive 8004 is then protected from UV photons by the coating layer 8008, so only the upward light rays 8005 leave the wing-Fresnel lens 8003. The adhesive material 8004 hidden behind the coating layer 8008 is thus protected from the UV photons by the coating layer 8008. As a result, the material degradation of the adhesive material 8004 is therefore minimized.

The height of the extension platform bottom above the substrate is in a range of 1 micron to 1 millimeter, but can be adjusted according to real applications.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. An LED device package structure, comprising:
an LED device mounted on a top surface of a substrate;
a wing-lens placed over the LED device and on the top surface of the substrate, wherein the wing-lens comprises: a lens, an extension structure formed around the lens and near a bottom edge of the lens, and a recess area formed between a bottom surface of the extension structure and the top surface of the substrate outside a sidewall of the lens at the bottom edge of the lens; and
an adhesive material applied in the recess area around the extension structure to seal the wing-lens to the substrate.

2. The LED device package structure according to claim 1, wherein a coating layer is disposed on the bottom surface of the extension structure and the sidewall of the lens at the bottom edge of the lens.

3. The LED device package structure according to claim 1, wherein the lens is a convex lens.

4. The LED device package structure according to claim 1, wherein the lens is a Fresnel lens.

5. The LED device package structure according to claim 1, wherein the extension structure around the lens comprises one of a ring shape, a square shape, and a polygon shape.

6. The LED device package structure according to claim 1, wherein the LED device emits ultraviolet (UV) light.

7. The LED device package structure according to claim 1, wherein the wing-lens comprises one of fused silica (quartz) or other UV transparent materials.

8. The LED device package structure according to claim 2, wherein a material in the coating layer comprises a metal or a combination of metals, for example, aluminum (Al), copper (Cu), or gold (Au), which are reflective to UV light, and wherein the coating layer is deposited via one of techniques, including but not limited to, physical vapor deposition (PVD), chemical vapor deposition (CVD), electroplating, or plasma-enhanced chemical vapor deposition (PECVD), etc.

9. The LED device package structure according to claim 2, wherein a material in the coating layer comprises a metal or a combination of metals, for example, tungsten (W), platinum (Pt), nickel (Ni), iron (Fe) or chromium (Cr), which are absorptive to UV light, wherein the coating layer is deposited via one of techniques, including but not limited to, physical vapor deposition (PVD), chemical vapor deposition (CVD), electroplating, or plasma-enhanced chemical vapor deposition (PECVD), etc.

10. The LED device package structure according to claim 2, wherein a material in the coating layer comprises inorganic materials, such as silicon oxide that absorbs or blocks UV photons.

11. The LED device package structure according to claim 1, wherein a height of the extension structure above the substrate is arranged to be in a range of 1 micron to 1 millimeter.

12. An LED device package structure, comprising:
an LED device mounted on a top surface of a substrate;
a wing-cap placed over the LED device and on the top surface of the substrate, wherein the wing-cap comprises: an optical window housing, an extension structure formed around the optical window housing and near a bottom edge of the optical window housing, and a recess area formed between a bottom surface of the extension structure and the top surface of the substrate outside a sidewall of the optical window housing at the bottom edge of the optical window housing; and
an adhesive material applied in the recess area around the extension structure to seal the optical window housing to the substrate.

13. The LED device package structure according to claim 12, wherein a coating layer is disposed on the bottom surface of the extension structure and the sidewall of the optical window housing at the bottom edge of the optical window housing.

14. The LED device package structure according to claim 12, wherein the optical window housing comprises a flat transparent window.

15. The LED device package structure according to claim 12, wherein the extension structure around the optical window housing comprises one of a ring shape, a square shape, and a polygon shape.

16. The LED device package structure according to claim 12, wherein the optical window housing comprises one of fused silica (quartz) or other UV transparent materials.

17. The LED device package structure according to claim 13, wherein a material in the coating layer comprises a metal or a combination of metals, for example, aluminum (Al), copper (Cu), or gold (Au), which are reflective to UV light, and wherein the coating layer is deposited via one of techniques, including but not limited to, physical vapor deposition (PVD), chemical vapor deposition (CVD), electroplating, or plasma-enhanced chemical vapor deposition (PECVD), etc.

18. The LED device package structure according to claim 13, wherein a material in the coating layer comprises a metal or a combination of metals, for example, tungsten (W), platinum (Pt), nickel (Ni), iron (Fe) or chromium (Cr), which are absorptive to UV light, and wherein the coating layer is deposited via one of techniques, including but not limited to, physical vapor deposition (PVD), chemical vapor deposition (CVD), electroplating, or plasma-enhanced chemical vapor deposition (PECVD), etc.

19. The LED device package structure according to claim 13, wherein a material in the coating layer comprises inorganic materials, such as silicon oxide that absorbs or blocks UV photons.

20. The LED device package structure according to claim 12, wherein a height of the extension structure above the substrate is arranged to be in a range of 1 micron to 1 millimeter.
